(19) United States
(12) Patent Application Publication
(10) Pub. No.: US 2024/0334744 A1
(43) Pub. Date: Oct. 3, 2024

(54) DISPLAY MODULE

(71) Applicant: Samsung Display Co., LTD., Yongin-si (KR)

(72) Inventor: KYUNGHEE LEE, Yongin-si (KR)

(21) Appl. No.: 18/431,280

(22) Filed: Feb. 2, 2024

(30) Foreign Application Priority Data
Apr. 3, 2023 (KR) 10-2023-0043534

(51) Int. Cl. H10K 59/122; H10K 59/80

(52) U.S. Cl. CPC H10K 59/122; H10K 59/8722; H10K 59/873; H10K 59/8792

(57) ABSTRACT

A display module divided into a light-emitting area and a non-light-emitting area includes a display panel including a base substrate, a pixel defining layer disposed on the base substrate with an opening defined therethrough to correspond to the light-emitting area, and a display element layer including light-emitting elements distinguished from each other by the pixel defining layer, an encapsulation substrate disposed on the display panel, a light control layer disposed on the encapsulation substrate and including a colorant, and a filling layer including at least one light-converted material having a first structure with a first absorptance to visible light and a second structure with a second absorptance greater than the first absorptance to the visible light. The filling layer is disposed between the display panel and the encapsulation substrate. When the at least one light-converted material absorbs ultraviolet-light, a structure thereof changes from the first structure to the second structure.

This application claims priority to Korean Patent Application No. 10-2023-0043534, filed on Apr. 3, 2023, and all the benefits accruing therefrom under 35 U.S.C. § 119, the content of which in its entirety is herein incorporated by reference.

### BACKGROUND

### 1. Field

Embodiments of the disclosure described herein relate to a display module including a filling layer.

### 2. Description of the Related Art

Various electronic devices used in a multimedia device such as a television, a mobile phone, a tablet computer, and a game machine are being developed. An electronic device may include various optical functional layers to provide a high-quality color image to a user.

Recently, research on a thin electronic device is being conducted to implement various types of electronic devices such as an electronic device including a curved surface, a rollable electronic device, or a foldable electronic device. For example, the thin electronic device may be implemented by reducing the number of optical functional layers and including an optical functional layer with various functions.

### SUMMARY

In a display module, a reflection phenomenon by external natural light may occur, and such reflection phenomenon deteriorates visibility of the display module. Accordingly, research on a panel structure to improve the visibility of the display module is being conducted.

Embodiments of the disclosure provide a display module with improved visibility in a turn-off state.

According to an embodiment, a display module divided into a light-emitting area and a non-light-emitting area includes a display panel including a base substrate, a pixel defining layer disposed on the base substrate with an opening defined therethrough to correspond to the light-emitting area, and a display element layer including light-emitting elements distinguished from each other by the pixel defining layer, an encapsulation substrate disposed on the display panel, a light control layer disposed on the encapsulation substrate and including a colorant, and a filling layer including at least one light-converted material having a first structure with a first absorptance with respect to the visible light and a second structure with a second absorptance greater than the first absorptance with respect to visible light, where the filling layer is disposed between the display panel and the encapsulation substrate, where each of the light-emitting elements includes a first electrode exposed by the opening, a hole transport area disposed on the first electrode, a light-emitting layer disposed on the hole transport area, an electron transport area disposed on the light-emitting layer, a second electrode disposed on the electron transport area, and a capping layer disposed on the second electrode, where when the at least one light-converted material absorbs ultraviolet light, a structure of the at least one light-converted material changes from the first structure to the second structure.

In an embodiment, a change of the structure of the at least one light-converted material between the first structure and the second structure may be reversible.

In an embodiment, the at least one light-converted material may have the first structure in a turn-on state of the display element layer and have the second structure in a turn-off state of the display element layer.

In an embodiment, when the at least one light-converted material is in the second structure, the at least one light-converted material may selectively absorb one of a first visible light, a second visible light having a wavelength range different from a wavelength range of the first visible light, and a third visible light having a wavelength range different from the wavelength range of the first visible light and the wavelength range of the second visible light.

In an embodiment, the at least one light-converted material may include a first light-converted material and a second light-converted material, and the first light-converted material and the second light-converted material may absorb light in different wavelength ranges, respectively.

In an embodiment, the first visible light may have a wavelength range equal to or higher than 410 nanometers (nm) and equal to or less than 500 nm, the second visible light may have a wavelength range equal to or higher than 550 nm and equal to or less than 750 nm, and the third visible light may have a wavelength range equal to or higher than 500 nm and equal to or less than 600 nm.

In an embodiment, the filling layer may include the at least one light-converted material in an amount equal to or greater than 0.1 weight percent (wt %) and equal to or less than 10.0 wt % based on a total weight of the filling layer.

In an embodiment, the at least one light-converted material may include at least one selected from a spiropyran-based compound and a diarylethene-based compound.

In an embodiment, the display module may further include an inorganic deposition layer disposed between the capping layer and the filling layer.

In an embodiment, the display module may not include a polarizer.

In an embodiment, the display module may further include a light blocking layer overlapping the non-light-emitting area and disposed between the filling layer and the encapsulation substrate.

According to an embodiment, a display module including a first light-emitting area which emits a first light, a second light-emitting area which emits a second light, and a third light-emitting area which emits a third light includes a display panel including a base substrate, a pixel defining layer disposed on the base substrate with a plurality of openings defined therethrough to correspond to the first to third light-emitting areas, respectively, and a display element layer including first to third light-emitting elements including light-emitting layers disposed in the openings, respectively, an encapsulation substrate disposed on the display panel, a sealing portion disposed between the display panel and the encapsulation substrate along an edge of the display panel, a filling layer including at least one light-converted material having a first structure which transmits all of the first to third lights when the display element layer is in a turn-on state, and a second structure which selectively absorbs one of a first visible light in a wavelength range equal to or greater than 410 nm and equal to or less than 500 nm, a second visible light in a wavelength range equal to or greater than 550 nm and equal to or less than 750 nm, and a third visible light in a wavelength range equal to or greater than 500 nm and equal to or less than 600 nm, where the filling layer is disposed in a space defined by the encapsulation substrate, the display panel, and the sealing portion, and a light control layer disposed on the encapsulation substrate and including a colorant, where each of the first to third light-emitting elements includes a first electrode exposed by each opening, a hole transport area disposed on the first electrode, a light-emitting layer disposed on the hole transport area, an electron transport area disposed on the light-emitting layer, a second electrode disposed on the electron transport area, a capping layer disposed on the second electrode, and an inorganic deposition layer disposed on the capping layer.

In an embodiment, a wavelength range of the first light may be equal to or higher than 625 nm and equal to or lower than 675 nm, a wavelength range of the second light may be equal to or higher than 500 nm and equal to or lower than 570 nm, and a wavelength range of the third light may be equal to or higher than 410 nm and equal to or lower than 480 nm.

In an embodiment, the colorant may absorb light in a wavelength range equal to or higher than 490 nm and equal to or lower than 505 nm and light in a wavelength range equal to or higher than 585 nm and equal to or lower than 600 nm.

In an embodiment, the at least one light-converted material may include a first light-converted material which selectively absorbs the first visible light when the at least one light-converted material is in the second structure, and a second light-converted material which selectively absorbs the second visible light when the at least one light-converted material is in the second structure.

In an embodiment, the filling layer may include the at least one light-converted material in an amount equal to or greater than 0.1 wt % and equal to or less than 10.0 wt % based on a total weight of the filling layer.

In an embodiment, the at least one light-converted material may include at least one selected from a spiropyran-based compound and a diarylethene-based compound.

In an embodiment, the at least one light-converted material in the first structure may absorb ultraviolet light and a structure of the at least one light-converted material may change from the first structure to the second structure.

In an embodiment, the at least one light-converted material in the second structure may absorb at least one selected from the first to third lights and the structure of the at least one light-converted material may change to the first structure.

In an embodiment, the filling layer may further include a base resin in which the at least one light-converted material is dispersed, and the base resin may include at least one selected from an acrylate-based resin, an epoxy-based resin, and a vinyl-based resin.

### BRIEF DESCRIPTION OF THE DRAWINGS

The above and other features of embodiments of the disclosure will become apparent by describing in detail embodiments thereof with reference to the accompanying drawings.

FIG. 1 is a perspective view of an electronic device according to an embodiment.

FIG. 2A is an exploded perspective view of an electronic device according to an embodiment.

FIG. 2B is a cross-sectional view of a display module.

FIG. 3 is a plan view of a display module according to an embodiment.

FIG. 4 is a cross-sectional view of a display module according to an embodiment.

FIG. 5 is an enlarged view of a filling layer according to an embodiment.

FIG. 6 is a diagram schematically illustrating a structural change of a light-converted material according to an embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

In the document, when a component (or a region, a layer, a portion, and the like) is referred to as being “on”, “connected to”, or “coupled to” another component, it means that the component may be directly disposed/connected/coupled on another component or a third component may be disposed between the component and another component.

In one example, in the document, “directly disposed” may mean that there is no layer, film, region, plate, and the like added between a portion and another portion of a layer, a film, a region, a plate, and the like. For example, “directly disposed” may mean a case of being disposed between two layers or two members without using an additional member such as an adhesive member or the like.

Like reference numerals refer to like components. In addition, in the drawings, thicknesses, ratios, and dimensions of components are exaggerated for effective description of technical content.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Terms such as first, second, and the like may be used to describe various components, but the components should not be limited by the terms. The above terms are used only for the purpose of distinguishing one component from another. For example, without departing from the scope of the disclosure, a first component may be named as a second component, and similarly, the second component may also be named as the first component.

In addition, terms such as “beneath”, “below”, “on”, “above” are used to describe the relationship of the components shown in the drawings. The above terms are relative concepts, and are described with reference to directions indicated in the drawings. Herein, “disposed on” may indicate a case of being disposed not only on top of but also beneath any one member.

Unless otherwise defined, all terms including technical and scientific terms used herein have the same meaning as commonly understood by one of ordinary skill in the art to which this disclosure belongs. In addition, terms, such as those defined in commonly used dictionaries, should be interpreted as having a meaning that is consistent with their meaning in the context of the relevant art and should not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, an electronic device and a display module according to embodiments of the disclosure will be described with reference to the accompanying drawings.

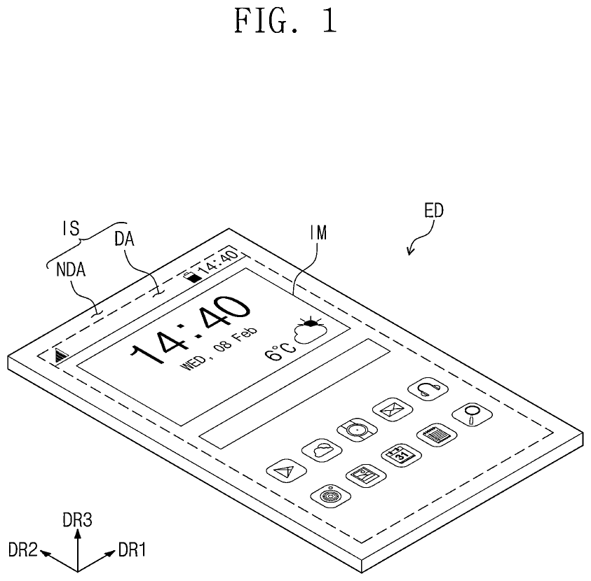

FIG. 1 is a perspective view of an electronic device according to an embodiment.

Referring to FIG. 1, an embodiment where an electronic device ED is a portable electronic device is illustrated in FIG. 1 as an example. However, the electronic device ED may be used not only for a large electronic device such as a television, a monitor, or an outdoor billboard, but also for a small and medium-sized electronic device such as a personal computer, a laptop computer, a personal digital terminal, a vehicle navigation unit, a game machine, a smartphone, a tablet personal computer (PC), and a camera. In addition, these are merely presented as embodiments, and the electronic device ED may be employed for other electronic devices as long as they do not deviate from the concept of the disclosure.

The electronic device ED may have a hexahedral shape having a thickness in a direction of a third direction axis DR3 on a plane defined by a first direction axis DR1 and a second direction axis DR2 intersecting each other. However, this is shown as an example, and the electronic device ED may have various shapes and is not limited to any one embodiment.

In an embodiment, an upper surface (or a front surface) and a lower surface (or a rear surface) of each member are defined based on the direction in which an image IM is displayed. The upper and lower surfaces are opposite to each other in the direction of the third direction axis DR3, and the normal direction of each of the upper and lower surfaces may be parallel to the direction of the third direction axis DR3.

Here, directions indicated by the first to third direction axes DR1, DR2, and DR3 are relative concepts and may be converted to other directions. Hereinafter, first to third directions are directions indicated by the first to third direction axes DR1, DR2, and DR3, and refer to the same reference numerals, respectively.

Here, the directions indicated by the first to third directions DR1, DR2, and DR3 are relative concepts and may be converted to other directions.

The electronic device ED may display the image IM via a display surface IS. The display surface IS includes a display area DA on which the image IM is displayed and a non-display area NDA adjacent to the display area DA. The non-display area NDA is an area in which the image is not displayed. The image IM may be a dynamic image or a static image. FIG. 1 shows an embodiment where the image IM includes a plurality of application icons, a clock, and the like as an example.

In an embodiment, the display area DA may have a rectangular shape. The non-display area NDA may surround the display area DA. However, this is merely an example, and the embodiment is not limited thereto. The shape of the display area DA and the shape of the non-display area NDA may be designed relatively. In an alternative embodiment, for example, the non-display area NDA may not exist on a front surface of the electronic device ED.

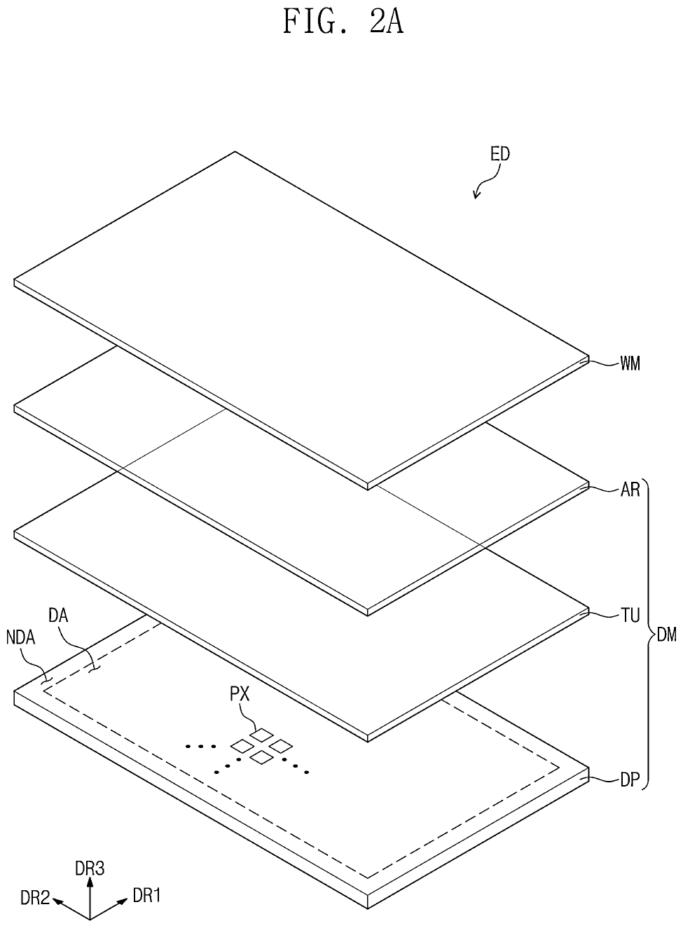

FIG. 2A is an exploded perspective view of an electronic device according to an embodiment. FIG. 2B is a cross-sectional view of a display module according to an embodiment.

Referring to FIG. 2A, the electronic device ED according to an embodiment may include a display module DM and a window WM sequentially stacked in the third direction axis DR3. The display module DM may include a display panel DP and a light control layer AR disposed on the display panel DP. The display module DM may further include a sensor layer TU disposed between the display panel DP and the light control layer AR.

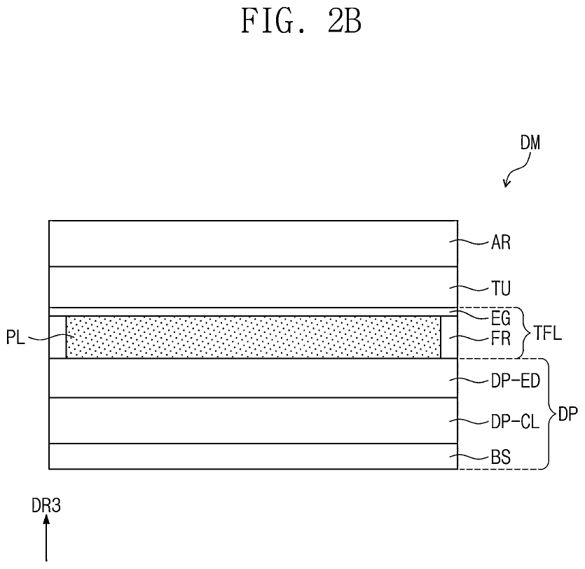

The display panel DP may include a plurality of pixels PX in an area corresponding to the display area DA. The plurality of pixels PX may correspond to a plurality of light-emitting areas PXA-R, PXA-B, and PXA-G (FIG. 3). The plurality of pixels PX may emit light in response to electrical signals. The display area DA may display the image IM (FIG. 1) generated by light from the plurality of pixels PX therein.

The display panel DP according to an embodiment may be a self-emissive display panel. In an embodiment, for example, the display panel DP may be a micro light emitting diode (LED) display panel, a nano LED display panel, an organic light-emitting display panel, or a quantum dot light-emitting display panel. However, this is only exemplary, and the self-emissive display panel is not limited thereto.

A light-emitting layer of the organic light-emitting display panel may include an organic light-emitting material. A light-emitting layer of the quantum dot light-emitting display panel may include quantum dots and/or quantum rods. The micro LED display panel may include a micro light-emitting diode element, which is a subminiature light-emitting element, and the nano LED display panel may include a nano light-emitting diode element. Hereinafter, for convenience of description, embodiment where the display panel DP is the organic light-emitting display panel will be described in detail.

The light control layer AR may be disposed on the display panel DP. The light control layer AR may be disposed at an uppermost portion of the display module DM. The light control layer AR may be an anti-reflection layer that reduces reflectance for external light incident from the outside. The light control layer AR may be a layer that selectively transmits light emitted from the display panel DP.

In an embodiment, the light control layer AR may not include a polarizing layer. Accordingly, light passing through the light control layer AR and incident to the display panel DP and the sensor layer TU may be unpolarized light.

The sensor layer TU may be disposed between the display panel DP and the light control layer AR. The sensor layer TU may acquire information to generate the image on the display panel DP by an external input. The external input may be an input of a user. The input of the user may include various types of external inputs such as a body part of the user, light, heat, a pen, or a pressure.

In an embodiment, for example, referring to FIG. 2B, the display panel DP may include a base substrate BS, a circuit layer DP-CL, a display element layer DP-ED, and an encapsulation layer TFL disposed on the display element layer DP-ED that are sequentially stacked. The encapsulation layer TFL may include an encapsulation substrate EG disposed on the display element layer DP-ED, a sealing portion FR disposed between the encapsulation substrate EG and the display element layer DP-ED, and a filling layer PL filling a space between the display element layer DP-ED, the encapsulation substrate EG, and the sealing portion FR.

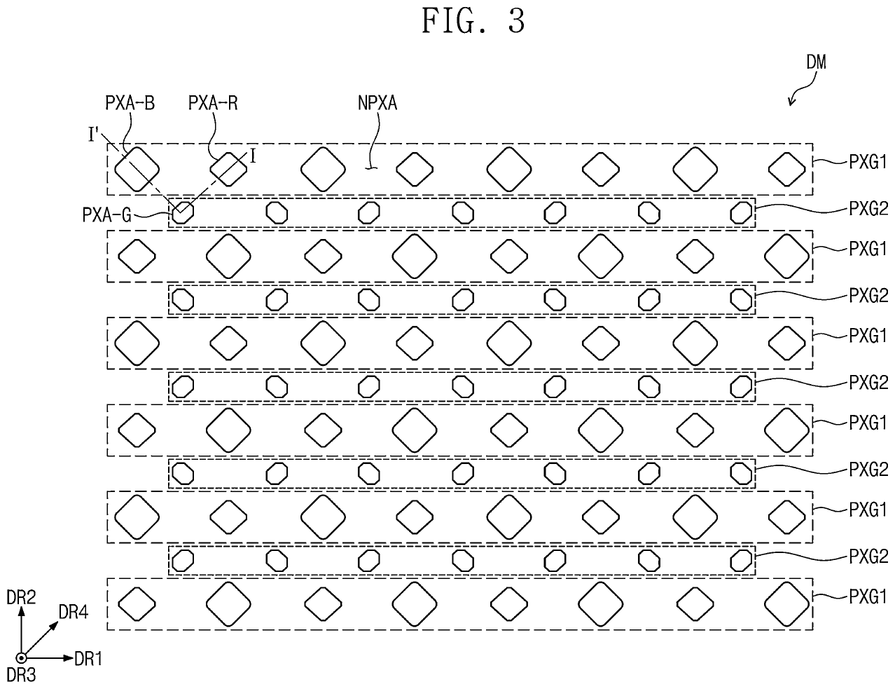

The sealing portion FR may function to attach the display panel DP and the encapsulation substrate EG to each other. In an embodiment, the sealing portion FR may include a frit. In such an embodiment, the frit, as a member including or made of a glass material that is a raw material of glass, may be hardened by laser exposure. The components other than the sealing portion FR will be described in greater detail later with reference to FIG. 4.

In an embodiment, for example, the display module DM may further include a light blocking layer (BM in FIG. 4) disposed between the encapsulation substrate EG and the filling layer PL. The light blocking layer BM may be disposed in a portion corresponding to a non-light-emitting area NPXA. The light blocking layer BM may be disposed to overlap a pixel defining layer PDL and not to overlap the first to third light-emitting areas PXA-R, PXA-B, and PXA-G.

The light blocking layer BM may prevent light leakage. The light blocking layer BM may be a light blocking member. The light blocking layer BM may include an organic light blocking material, a black pigment, a black dye, or the like.

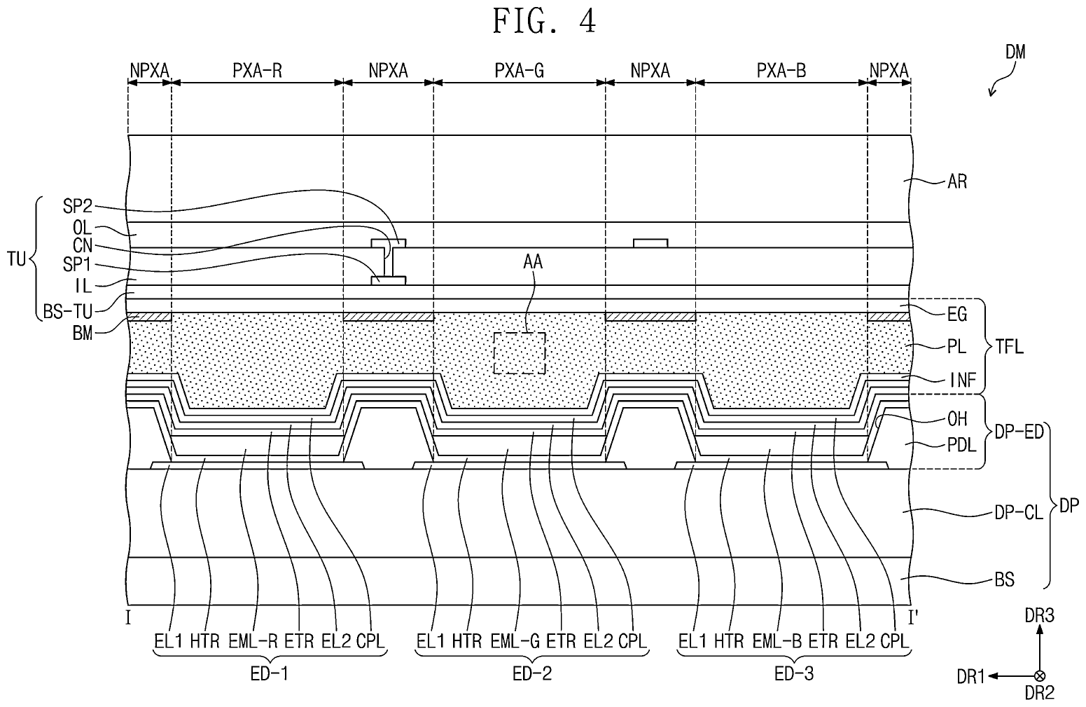

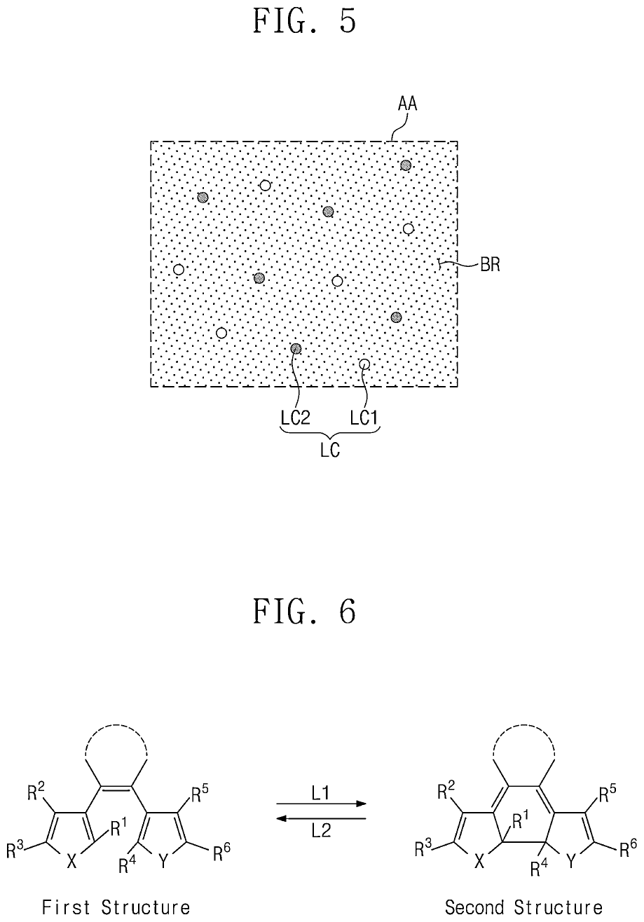

FIG. 3 is a plan view of a display module according to an embodiment. FIG. 4 is a cross-sectional view of a display module according to an embodiment. FIG. 5 is an enlarged view of a filling layer according to an embodiment. FIG. 6 is a diagram schematically illustrating a structural change of a light-converted material of an embodiment. Particularly, FIG. 4 is a cross-sectional view of a portion taken along line I-I′ in FIG. 3 of a display module according to an embodiment, and FIG. 5 is an enlarged view of a portion AA shown in FIG. 4.

Referring to FIGS. 3 and 4, an embodiment of the display module DM may include the non-light-emitting area NPXA and the light-emitting areas PXA-R, PXA-G, and PXA-B. Each of the light-emitting areas PXA-R, PXA-G, and PXA-B may be an area from which light generated by each of light-emitting elements ED-1, ED-2, and ED-3 is emitted.

The light-emitting areas PXA-R, PXA-G, and PXA-B may be classified into a plurality of groups based on colors of light generated by the light-emitting elements ED-1, ED-2, and ED-3. In an embodiment of the display module DM shown in FIGS. 3 and 4, the three light-emitting areas PXA-R, PXA-G, and PXA-B that emit red light, green light, and blue light, respectively, are shown as an example.

The first light-emitting area PXA-R may emit a first light in a wavelength range equal to or higher than 625 nanometers (nm) and equal to or lower than 675 nm. The second light-emitting area PXA-G may emit a second light in a wavelength range equal to or higher than 500 nm and equal to or lower than 570 nm. The third light-emitting area PXA-B may emit a third light in a wavelength range equal to or higher than 410 nm and equal to or lower than 480 nm.

Area sizes (i.e., planar areas) of the light-emitting areas PXA-R, PXA-G, and PXA-B may be different from each other. Here, the area size may mean an area size or a planar aera when viewed on a plane or when viewed in the third direction DR3. The light-emitting areas PXA-R, PXA-G, and PXA-B may have the different area sizes depending on the colors of light emitted from light-emitting layers of the respective light-emitting elements ED-1, ED-2, and ED-3. For example, referring to FIG. 3, in an embodiment of the display module DM, the third light-emitting area PXA-B of the light-emitting element that emits blue light may have the largest area size on the plane and the second light-emitting area PXA-G of the light-emitting element that emits green light may have the smallest area size on the plane. However, this is merely an example, and the embodiment is not limited thereto.

In an alternative embodiment, the light-emitting areas PXA-R, PXA-G, and PXA-B may emit light of colors other than red, green, and blue, the light-emitting areas PXA-R, PXA-G, and PXA-B may have a same area size, or the light-emitting areas PXA-R, PXA-G, and PXA-B may be provided with an area size ratio different from that shown in FIG. 3.

In an embodiment, for example, the light-emitting areas PXA-R, PXA-G, and PXA-B may be grouped into a first light-emitting group PXG1 including the first light-emitting area PXA-R and the third light-emitting area PXA-B, and a second light-emitting group PXG2 disposed in a different row from the first light-emitting group PXG1 and including the second light-emitting area PXA-G. The first light-emitting group PXG1 and the second light-emitting group PXG2 may be alternately arranged in the second direction DR2.

The third light-emitting area PXA-B and the first light-emitting area PXA-R may be spaced apart from each other in the first direction DR1. The third light-emitting area PXA-B and the first light-emitting area PXA-R may be alternately disposed in the first direction DR1. Each of the first light-emitting area PXA-R and the third light-emitting area PXA-B and the second light-emitting area PXA-G may not overlap each other in the second direction DR2. The first light-emitting area PXA-R and the third light-emitting area PXA-B may be alternately disposed in the second direction DR2.

The first light-emitting area PXA-R and the second light-emitting area PXA-G may be spaced apart from each other in a fourth direction DR4. The third light-emitting area PXA-B and the second light-emitting area PXA-G may be spaced apart from each other in the fourth direction DR4. The fourth direction DR4 may be defined as a direction between the first direction DR1 and the second direction DR2.

The arrangement structure of the light-emitting areas PXA-R, PXA-G, and PXA-B shown in FIG. 3 may be defined as a PENTILE® structure. However, the arrangement structure of the light-emitting areas PXA-R, PXA-G, and PXA-B in the display module DM according to embodiments is not limited to the arrangement structure shown in FIG. 3. For example, in an alternative embodiment, the light-emitting areas PXA-R, PXA-G, and PXA-B may have a stripe structure in which the red light-emitting area PXA-R, the green light-emitting area PXA-G, and the blue light-emitting area PXA-B are sequentially and alternately arranged along the first direction axis DR1.

The light-emitting areas PXA-R, PXA-G, and PXA-B may be areas distinguished from each other by the pixel defining layer PDL. The non-light-emitting areas NPXA, as areas between the neighboring light-emitting areas PXA-R, PXA-G, and PXA-B, may be areas corresponding to the pixel defining layer PDL. In an embodiment, for example, each of the light-emitting areas PXA-R, PXA-G, and PXA-B may correspond to the pixel PX (FIG. 2A).

The pixel defining layer PDL may distinguish the light-emitting elements ED-1, ED-2, and ED-3 from each other. The light-emitting layers EML-R, EML-G, and EML-B of the respective light-emitting elements ED-1, ED-2, and ED-3 may be distinguished from each other by being respectively disposed in openings OH defined in the pixel defining layer PDL.

The display element layer DP-ED may include the pixel defining layer PDL, the light-emitting elements ED-1, ED-2, and ED-3 disposed between portions of the pixel defining layer PDL, and an inorganic deposition layer INF disposed on the light-emitting elements ED-1, ED-2, and ED-3.

The display panel DP may include the base substrate BS, the circuit layer DP-CL, and the display element layer DP-ED sequentially stacked. The display element layer DP-ED may include the pixel defining layer PDL, the light-emitting elements ED-1, ED-2, and ED-3 respectively disposed in the openings OH defined in the pixel defining layer PDL, and the encapsulation layer TFL disposed on the light-emitting elements ED-1, ED-2, and ED-3.

The base substrate BS may be rigid or flexible. The base substrate BS may be a polymer substrate, a plastic substrate, a glass substrate, a metal substrate, a composite material substrate, or the like. The base substrate BS may have a multi-layer structure or a single-layer structure. In an embodiment, the base substrate BS may include a synthetic resin film, and the base substrate BS may have the multi-layer structure including a plurality of synthetic resin film layers. The synthetic resin film may include polyimide-based, acryl-based, vinyl-based, epoxy-based, urethane-based, cellulose-based, and perylene-based materials, but the synthetic resin film material is not limited to the above examples.

The circuit layer DP-CL may be disposed on the base substrate BS. The circuit layer DP-CL may include an insulating layer, a semiconductor pattern, a conductive pattern, a signal line, and the like. The circuit layer DP-CL may include a plurality of transistors (not shown) including or formed of the semiconductor pattern, the conductive pattern, the signal line, and the like. Each of the transistors (not shown) may include a control electrode, an input electrode, and an output electrode. In an embodiment, for example, the circuit layer DP-CL may include a switching transistor and a driving transistor for driving the light-emitting elements ED-1, ED-2, and ED-3.

The display element layer DP-ED may be disposed on the circuit layer DP-CL. The display element layer DP-ED may include the pixel defining layer PDL and the light-emitting elements ED-1, ED-2, and ED-3.

The light-emitting elements ED-1, ED-2, and ED-3 may include the plurality of light-emitting elements ED-1, ED-2, and ED-3. Each of the light-emitting elements ED-1, ED-2, and ED-3 may include a first electrode EL1, a hole transport area HTR, a corresponding one of the light-emitting layers EML-R, EML-G, and EML-B, an electron transport area ETR, a second electrode EL2, and a capping layer CPL. The first light-emitting element ED-1 may include the first light-emitting layer EML-R overlapping the first light-emitting area PXA-R. The second light-emitting element ED-2 may include the second light-emitting layer EML-G overlapping the second light-emitting area PXA-G. The third light-emitting element ED-3 may include the third light-emitting layer EML-B overlapping the third light-emitting area PXA-B.

The pixel defining layer PDL may be disposed on the circuit layer DP-CL. The predetermined pixel openings OH may be defined in the pixel defining layer PDL. The pixel openings OH defined in the pixel defining layer PDL may correspond to the plurality of light-emitting areas PXA-R, PXA-G, and PXA-B, respectively. The non-light-emitting areas NPXA, as the areas between the neighboring light-emitting areas PXA-R, PXA-G, and PXA-B, may be areas corresponding to the pixel defining layer PDL.

The pixel defining layer PDL may include an organic resin or an inorganic material. In an embodiment, for example, the pixel defining layer PDL may include a polyacrylate-based resin, a polyimide-based resin, silicon nitride (SiNₓ), silicon oxide (SiOₓ), silicon oxynitride (SiOₓN_{y}), or the like.

In FIG. 4, an embodiment in which the light-emitting layers EML-R, EML-G, and EML-B of the respective light-emitting elements ED-1, ED-2, and ED-3 are respectively patterned and disposed in the openings OH defined in the pixel defining layer PDL, and the hole transport area HTR, the electron transport area ETR, the capping layer CPL, and the second electrode EL2 are provided as common layers is shown. However, the embodiment is not limited thereto, and in an alternative embodiment, at least one selected from the hole transport area HTR, the electron transport area ETR, the capping layer CPL, and the second electrode EL2 may be patterned and disposed in the opening OH.

In the light-emitting elements ED-1, ED-2, and ED-3, the first electrode EL1 may be disposed on the circuit layer DP-CL. The first electrode EL1 may be an anode or a cathode. In addition, the first electrode EL1 may be a pixel electrode. The first electrode EL1 may be a transmissive electrode, a transflective electrode, or a reflective electrode.

The hole transport area HTR may be disposed between the first electrode EL1 and the light-emitting layer EML. The hole transport area HTR may include at least one selected from a hole injection layer, a hole transport layer, and an electron blocking layer. The hole transport area HTR may be disposed as the common layer to overlap the light-emitting areas PXA-R, PXA-G, and PXA-B and the entire pixel defining layer PDL that distinguishes the light-emitting areas PXA-R, PXA-G, and PXA-B from each other. However, the embodiment may not be limited thereto, and the hole transport area HTR may be provided as patterns separated from each other to respectively correspond to the light-emitting areas PXA-R, PXA-G, and PXA-B.

Each of the light-emitting layers EML-R, EML-G, and EML-B may be disposed on the first electrode EL1. The light-emitting layer EML-R, EML-G, and EML-B may include first to third light-emitting layers EML-R, EML-G, and EML-B. The first light-emitting layer EML-R may overlap the first light-emitting area PXA-R and may emit the first light. The second light-emitting layer EML-G may overlap the second light-emitting area PXA-G and may emit the second light. The third light-emitting layer EML-B may overlap the third light-emitting area PXA-B and may emit the third light. In the light-emitting elements ED-1, ED-2, and ED-3 according to an embodiment, the first light to the third light may be light having substantially different wavelength ranges. In an embodiment, for example, the first light may be red light in the wavelength range equal to or higher than 625 nm and equal to or lower than 675 nm. In an embodiment, for example, the second light may be green light in the wavelength range equal to or higher than 500 nm and equal to or lower than 570 nm. In an embodiment, for example, the third light may be blue light in the wavelength range equal to or higher than 410 nm and equal to or lower than 480 nm.

The electron transport area ETR may be disposed between the light-emitting layer EML-R, EML-G, or EML-B and the second electrode EL2. The electron transport area ETR may include at least one selected from an electron injection layer, an electron transport layer, and a hole blocking layer. The electron transport area ETR may be disposed as the common layer to overlap the light-emitting areas PXA-R, PXA-G, and PXA-B and the entire pixel defining layer PDL that distinguishes the light-emitting areas PXA-R, PXA-G, and PXA-B from each other. However, the embodiment may not be limited thereto, and the electron transport area ETR may be provided as patterns separated from each other to respectively correspond to the light-emitting areas PXA-R, PXA-G, and PXA-B.

The second electrode EL2 is provided on the electron transport area ETR. The second electrode EL2 may be a common electrode. The second electrode EL2 may be a cathode or an anode, but the embodiment may not be limited thereto. in an embodiment, for example, where the first electrode EL1 is the anode, the second electrode EL2 may be the cathode. In an alternative embodiment, where the first electrode EL1 is the cathode, the second electrode EL2 may be the anode. The second electrode EL2 may be the transmissive electrode, the transflective electrode, or the reflective electrode.

The capping layer CPL may be further disposed on the second electrode EL2. The capping layer CPL may be composed of or defined by multiple layers or a single layer. In an embodiment, the capping layer CPL may be an organic layer or an inorganic layer. In an embodiment, for example, where the capping layer CPL includes an inorganic material, the inorganic material may include an alkali metal compound such as LiF, an alkaline earth metal compound such as MgF₂, SiON, SiNₓ, SiO_{y}, or the like. In an embodiment, for example, where the capping layer CPL contains an organic material, the organic material may include α-NPD, NPB, TPD, m-MTDATA, Alq₃, CuPc, TPD15(N4,N4,N4′,N4′-tetra (biphenyl-4-yl) biphenyl-4,4′-diamine), TCTA(4,4′,4″-Tris (carbazol-9-yl) triphenylamine), or the like, or include an epoxy resin or acrylate such as methacrylate. However, the embodiment is not limited thereto.

In an embodiment, for example, a refractive index of the capping layer CPL may be equal to or greater than 1.6. In such an embodiment, the refractive index of the capping layer CPL may be equal to or greater than 1.6 for light in a wavelength range equal to or higher than 550 nm and equal to or lower than 660 nm.

The inorganic deposition layer INF may be disposed on the capping layer CPL. The inorganic deposition layer INF may be directly disposed on the capping layer CPL. The inorganic deposition layer INF may be a layer for preventing external light from being reflected by the second electrode EL2 of the light-emitting elements ED-1, ED-2, and ED-3. In such an embodiment, destructive interference may occur between light reflected from a surface of the inorganic deposition layer INF and light reflected from the second electrode EL2, thereby reducing an amount of external light reflected from a surface of the second electrode EL2. Thicknesses of the inorganic deposition layer INF and the capping layer CPL may be adjusted in a way such that the destructive interference occurs between light reflected from the surface of the inorganic deposition layer INF and light reflected from the second electrode EL2.

The inorganic deposition layer INF may include an inorganic material having a refractive index equal to or greater than 1.0 and a light absorption coefficient equal to or greater than 0.5. The inorganic deposition layer INF may be formed via a thermal evaporation process and may include an inorganic material with a melting point equal to or lower than 1000° C. The inorganic deposition layer INF may include, for example, at least one selected from bismuth (Bi) and ytterbium (Yb). The material forming the inorganic deposition layer INF may include or be made of bismuth (Bi), ytterbium (Yb), or a YbₓBi_{y} mixed deposition material. The encapsulation layer TFL may be directly disposed on at least a portion of the inorganic deposition layer INF.

The encapsulation layer TFL may be disposed on the display element layer DP-ED. The encapsulation layer TFL may protect the light-emitting elements ED-1, ED-2, and ED-3 from moisture and oxygen and protect the light-emitting elements ED-1, ED-2, and ED-3 from foreign substances such as dust particles.

The encapsulation layer TFL may include the encapsulation substrate EG disposed on the display element layer DP-ED, the sealing portion FR disposed between the display element layer DP-ED and the encapsulation substrate EG, and the filling layer PL filling the space defined by the encapsulation substrate EG, the display element layer DP-ED, and the sealing portion FR.

The encapsulation substrate EG may be rigid. The encapsulation substrate EG may protect the light-emitting elements ED-1, ED-2, and ED-3 from the external moisture and oxygen and the foreign substances such as the dust particles. In an embodiment, for example, the encapsulation substrate EG may include glass. However, the embodiment may not be limited thereto, and the material of the encapsulation substrate EG may not be limited thereto and may be a metal substrate or a polymer substrate.

The sealing portion FR may support the encapsulation substrate EG. The sealing portion FR may attach the encapsulation substrate EG and the display element layer DP-ED to each other. The sealing portion FR may be disposed at an edge of the display element layer DP-ED. The sealing portion FR may not cover at least a portion of the display element layer DP-ED to be exposed. Accordingly, the space may be defined by the display element layer DP-ED, the encapsulation substrate EG, and the sealing portion FR. In an embodiment, for example, the sealing portion FR may be a member that seals the space defined by the display element layer DP-ED, the encapsulation substrate EG, and the sealing portion FR.

The sealing portion FR may protect the light-emitting elements ED-1, ED-2, and ED-3 from the external moisture and oxygen and the foreign substances such as the dust particles together with the encapsulation substrate EG. In an embodiment, for example, the sealing portion FR may include the frit. However, this is merely an example, and the embodiment is not limited thereto. The sealing portion FR may include glass, metal, or a polymer resin.

The filling layer PL may be disposed between the display panel DP and the encapsulation substrate EG. The filling layer PL may fill the space defined by the display element layer DP-ED, the encapsulation substrate EG, and the sealing portion FR. The filling layer PL may protect the light-emitting elements ED-1, ED-2, and ED-3 from an external impact by filling the space defined by the display element layer DP-ED, the encapsulation substrate EG, and the sealing portion FR.

Referring to FIGS. 4 to 6, in an embodiment, the filling layer PL may include at least one light-converted material LC. In an embodiment, for example, the filling layer PL may include one light-converted material LC or the at least two different light-converted materials LC.

In an embodiment, the light-converted material LC may have a first structure that transmits light across an entire visible spectrum and a second structure that selectively absorbs light in a portion of the visible spectrum. In an embodiment, the light-converted material LC may absorb ultraviolet light in the first structure and change into the second structure. In an embodiment, the light-converted material LC may absorb light in the visible spectrum in the second structure and change into the first structure. That is, the structure of the light-converted material LC may reversibly change between the first structure and the second structure based on a wavelength band of irradiated light.

Referring to FIG. 6, when the light-converted material LC in the first structure absorbs the ultraviolet light, a ring-closing reaction may occur therein and the structure thereof may change to the second structure. When a light-converted material LC in the second structure absorbs the visible light, a ring-opening reaction may occur therein and the structure thereof may change to the first structure. The first structure and the second structure may have different conjugation lengths, and accordingly, wavelength bands of absorbed light by the light-converted material LC may be different from each other. However, the first structure becoming the second structure via the ring-closing reaction and the second structure becoming the first structure via the ring-opening reaction is merely an example, and the embodiment is not limited thereto. As long as the first structure transmits most of light in the visible spectrum and the second structure selectively transmits light in the visible spectrum, embodiments are not particularly limited.

The light-converted material LC may include at least one selected from spiropyran, spirooxazine, diaryl ethene, azobenzene, hexaarylbiimidazole, and spiroperimidine. However, this is merely an example, and the embodiment is not limited thereto.

The light-converted material LC in the first structure may have a first absorptance for the visible light. The light-converted material LC in the second structure may have a second absorptance greater than the first absorptance for the visible light. The light-converted material LC in the first structure may have a first transmittance for the visible light and the light-converted material LC in the second structure have a second transmittance less than the first transmittance for the visible light.

In an embodiment, when the display element layer DP-ED is in a turn-on state, the light-converted material LC may have the first structure. When the display element layer DP-ED is in the turn-on state, because the light-converted material LC has the first structure, the filling layer PL may transmit the first light to the third light respectively emitted from the light-emitting elements ED-1, ED-2, and ED-3. Accordingly, the display module DM may exhibit high light emission efficiency.

In such an embodiment, for example, when the display element layer DP-ED is in a turn-off state, the light-converted material LC may have the second structure. When the display element layer DP-ED is in the turn-off state, because the light-converted material LC has the second structure, the filling layer PL may selectively absorb light in only the portion of the visible spectrum. In an embodiment, for example, the light-converted material LC in the second structure may selectively absorb one selected from a first visible light in a wavelength range equal to or higher than 410 nm and equal to or lower than 550 nm, a second visible light in a wavelength range equal to or higher than 550 nm and equal to or lower than 600 nm, and a third visible light in a wavelength range equal to or higher than 600 nm and equal to or lower than 750 nm. Accordingly, a color viewed by the user in the turn-off state may be adjusted.

In such an embodiment, when the display element layer DP-ED is in the turn-off state, reflected light of external light that has been incident on the display panel DP may be viewed by the user. The display module DM may adjust a color of reflected light to be close to neutral black by including the filling layer PL including the light-converted material LC. Hereinafter, the turn-off state and the turn-on state are defined as the case in which the display element layer DP-ED is turned off and the case in which the display element layer DP-ED is turned on, respectively.

When selectively absorbing the first visible light, the light-converted material LC in the second structure may exhibit a yellow color. Because yellow and blue are complementary colors, when yellow light and blue light are mixed with each other, the mixed color may become black. That is, the display module DM may prevent reflected light of the display panel DP from viewed by the user as bluish by the filling layer PL including the light-converted material LC that selectively absorbs the first visible light in the second structure.

When selectively absorbing the second visible light, the light-converted material LC in the second structure may exhibit a magenta color. Because magenta and green are complementary colors, when magenta light and green light are mixed with each other, the mixed color may become black. That is, the display module DM may prevent reflected light of the display panel DP from viewed by the user as greenish by the filling layer PL including the light-converted material LC that selectively absorbs the second visible light in the second structure.

When selectively absorbing the third visible light, the light-converted material LC in the second structure may exhibit a cyan color. Because cyan and red are complementary colors, when cyan light and red light are mixed with each other, the mixed color may become black. That is, the display module DM may prevent reflected light of the display panel DP from viewed by the user as reddish by the filling layer PL including the light-converted material LC that selectively absorbs the third visible light in the second structure.

In an embodiment, as shown in FIG. 5, the light-converted material LC may include a first light-converted material LC1 and the second light-converted material LC2 different from the first light-converted material LC1. The first light-converted material LC1 and the second light-converted material LC2 may absorb light in different wavelength ranges, respectively. In an embodiment, the first light-converted material LC1 may selectively absorb one of the first visible light to the third visible light, and the second light-converted material LC2 may absorb another of the first visible light to the third visible light, which is not absorbed by the first light-converted material LC1. In an embodiment, for example, the first light-converted material LC1 may selectively absorb the first visible light, and the second light-converted material LC2 may selectively absorb the second visible light.

In an embodiment, the filling layer PL may include the light-converted material LC in an amount equal to or greater than 0.1 weight percent (wt %) and equal to or less than 10.0 wt % based on a total weight of the filling layer PL. The display module DM may exhibit high light emission efficiency in the turn-on state and adjust the color of reflected light to become neutral black in the turn-off state by the filling layer PL including the light-converted material LC in the amount equal to or greater than 0.1 wt % and equal to or less than 10.0 wt % based on the total weight of the filling layer PL. If the filling layer PL includes the light-converted material LC in an amount less than 0.1 wt % based on the total weight of the filling layer PL, absorption of external light is insufficient in the turn-off state, so that there is a limitation in adjusting the color of reflected light to become neutral black. If the filling layer PL includes the light-converted material LC in an amount greater than 10.0 wt % based on the total weight of the filling layer PL, some of the light-converted materials LC may absorb the visible light in the turn-on state, resulting in a decrease in the light emission efficiency. In addition, if the filling layer PL includes the light-converted material LC in the amount greater than 10.0 wt % based on the total weight of the filling layer PL, some of the light-converted materials LC may absorb the visible light in the turn-on state, which may affect the color of light emitted from the display module DM.

In an embodiment, the filling layer PL may further include a base resin BR in which the at least one light-converted material LC is dispersed. The base resin BR may include a polymer resin. In an embodiment, for example, the base resin BR may include an acrylic resin, an epoxy-based resin, or a vinyl-based resin. However, this is merely an example, and the embodiment is not limited thereto. In an embodiment, for example, the filling layer PL may further include other additives including an inhibitor and a radical initiator.

Referring back to FIG. 4, the light control layer AR may be disposed on the encapsulation substrate EG. The light control layer AR may be disposed on the display panel DP. The light control layer AR may overlap an entirety of the display element layer DP-ED. The light control layer AR may overlap an entirety of each of the first light-emitting element ED-1, the second light-emitting element ED-2, and the third light-emitting element ED-3. The light control layer AR may be disposed to correspond to all of the light-emitting areas PXA-R, PXA-G, and PXA-B and the non-light-emitting areas NPXA. The light control layer AR may be provided as or defined by a single layer.

In an alternative embodiment, the light control layer AR may be disposed on the display panel DP. The light control layer AR may overlap the entirety of the display element layer DP-ED. The light control layer AR may overlap the entirety of each of the first light-emitting element ED-1, the second light-emitting element ED-2, and the third light-emitting element ED-3. The light control layer AR may be provided as one continuous layer. The light control layer AR may cover a front surface of the display panel DP and protect the display panel DP. The light control layer AR may improve a color reproduction range by absorbing a portion of light emitted from the display panel DP and transmitting the remaining thereof. The color reproduction range refers to a range of color that a display device may render. In an embodiment, for example, the color reproduction range may be improved by selectively absorbing light in a specific wavelength range.

In an embodiment, the light control layer AR disposed on the display panel DP may not include the polarizing layer and may be a layer in which dye and/or pigment is dispersed in the base resin. In such an embodiment, as the light control layer AR does not include the polarizing layer, light that passes through the light control layer AR and is incident on the display panel DP and the sensor layer TU may be unpolarized light. The display panel DP and the sensor layer TU may receive the unpolarized light from above the light control layer AR.

The light control layer AR may have high light absorptance in a specific wavelength range. The light control layer AR may include a colorant having the high light absorptance in the specific wavelength range. The colorant may have the high light absorptance in the specific wavelength range. The colorant may have the high light absorptance in at least one wavelength range. The colorant may be a material that absorbs light having a maximum absorption wavelength in a wavelength range excluding the wavelength ranges of the first light, the second light, and the third light. In an embodiment, for example, the colorant may be a material that absorbs light in a wavelength range equal to or higher than 490 nm and equal to or less than 505 nm and light in a wavelength range equal to or higher than 585 nm and equal to or less than 600 nm, and transmits light in other wavelength ranges. The colorant may have the maximum absorption wavelength in the wavelength range equal to or higher than 490 nm and equal to or less than 505 nm and the wavelength range equal to or higher than 585 nm and equal to or less than 600 nm. As the colorant contained in the light control layer AR absorbs light in the specific wavelength range and transmits light in other wavelength ranges, reflection by external light may be effectively prevented and the color of light emitted from the display panel DP may be adjusted.

The colorant may include at least one selected from the dye and the pigment. In an embodiment, for example, the colorant in the light control layer AR may include at least one selected from an anthraquinone-based compound, a phthalocyanine-based compound, an azo-based compound, a perylene-based compound, a xanthene-based compound, a diimmonium-based compound, a dipyrromethene-based compound, a tetraazaporphyrin-based compound, a porphyrin-based compound, a squaryllium-based compound, an oxazine-based compound, a triarylmethane-based compound, and a cyanine-based compound. In an embodiment, for example, the light control layer AR may include at least one selected from the tetraazapoporphyrin-based compound, the cyanine-based compound, the squaryllium-based compound, and the oxazine-based compound, or a combination thereof.

The light control layer AR may include the colorant in an amount equal to or greater than 0.01 wt % and equal to or less than 5.00 wt % based on a total weight of the light control layer AR. If the light control layer AR includes the colorant in an amount less than 0.01 wt %, the color reproduction range may not be improved because light in the specific wavelength range is not sufficiently absorbed. If the light control layer AR includes the colorant in an amount greater than 5.00 wt %, aggregation of the colorant may occur.

In addition, in an embodiment of the display module DM, the light control layer AR may be disposed to correspond to the non-light-emitting areas NPXA, and may not include walls (not shown) for blocking external light. Accordingly, in the light control layer AR, a transmission amount of external light may be the same in portions corresponding to the light-emitting areas PXA-R, PXA-G, and PXA-B and portions corresponding to the non-light-emitting areas NPXA. External light that passes through the light control layer AR and is incident on the display panel DP may be reflected to the outside by the display panel DP, and the light reflected to the outside by the display panel DP may affect a color of the display module DM viewed by the user in the turn-off state.

Specifically, compared to a case in which the light control layer AR includes the walls (not shown) that blocks external light, an amount of light that passes through the light control layer AR and is incident on the display panel DP may increase in the case in which the light control layer AR does not include the walls (not shown) that blocks external light as in an embodiment of the display module DM. Accordingly, an amount of light reflected to the outside by the display panel DP may increase, and the color of the display module DM viewed by the user may be adversely affected.

The sensor layer TU is disposed between the display panel DP and the light control layer AR. The sensor layer TU may include a sensor base layer BS-TU, a first conductive layer SP1, an inorganic insulating layer IL, a second conductive layer SP2, and an organic insulating layer OL. The first conductive layer SP1 may be disposed on the sensor base layer BS-TU. The inorganic insulating layer IL may cover the first conductive layer SP1 and may be disposed on the base layer BS-TU and the first conductive layer SP1. The second conductive layer SP2 may be disposed on the inorganic insulating layer IL. The organic insulating layer OL may cover the second conductive layer SP2 and may be disposed on the inorganic insulating layer IL and the second conductive layer SP2.

In an embodiment, the sensor base layer BS-TU may be an inorganic layer including at least one selected from silicon nitride, silicon oxynitride, and silicon oxide. Alternatively, the sensor base layer BS-TU may be an organic layer including the epoxy resin, the acrylic resin, or an imide-based resin. The sensor base layer BS-TU may have a single-layer structure or a structure of multiple layers stacked along the third direction DR3. The sensor base layer BS-TU may be directly disposed on the encapsulation layer TFL.

Each of the first conductive layer SP1 and the second conductive layer SP2 may have a single-layer structure or a structure of multiple layers stacked along the third direction DR3. The conductive layers SP1 and SP2 having the single-layer structure may include a metal layer or a transparent conductive layer. The metal layer may include molybdenum, silver, titanium, copper, aluminum, or an alloy thereof. The transparent conductive layer may include transparent conductive oxide such as indium tin oxide (ITO), indium zinc oxide (IZO), zinc oxide (ZnO), indium zinc tin oxide (IZTO), or the like. In addition, the transparent conductive layer may include a conductive polymer such as PEDOT, a metal nanowire, graphene, or the like.

The conductive layers SP1 and SP2 having the multi-layer structure may include metal layers. The metal layers may have, for example, a three-layer structure of titanium (Ti)/aluminum (Al)/titanium (Ti). The conductive layers SP1 and SP2 having the multi-layer structure may include at least one metal layer and at least one transparent conductive layer.

The inorganic insulating layer IL may include at least one selected from aluminum oxide, titanium oxide, silicon oxide, silicon oxynitride, zirconium oxide, and hafnium oxide.

A contact hole CN may be defined in the inorganic insulating layer IL. The first conductive layer SP1 and the second conductive layer SP2 may be electrically connected to each other via the contact hole CN. The contact hole CN may be filled with a material of the second conductive layer SP2. Although FIG. 4 shows one contact hole CN defined in the inorganic insulating layer IL for convenience of illustration, the embodiment may not be limited thereto, and a plurality of contact holes may be defined in the inorganic insulating layer.

The organic insulating layer OL may cover the inorganic insulating layer IL and the second conductive layer SP2. The organic insulating layer OL may include at least one selected from the acrylic resin, a methacrylic resin, a polyisoprene-based resin, the vinyl-based resin, the epoxy-based resin, a urethane-based resin, a cellulose-based resin, a siloxane-based resin, the polyimide-based resin, a polyamide-based resin, and a perylene-based resin.

In embodiments of the invention, the display module includes the filling layer disposed between the display element layer and the encapsulation substrate and including the light-converted material having the first structure that transmits light across the visible spectrum and the second structure that selectively transmits light in the portion of the visible spectrum. The display module includes the filling layer including the light-converted material, thereby having high light emission efficiency in the turn-on state and exhibiting neutral black in the turn-off state because the reflection of external light decreases. Accordingly, the display module may adjust the color of the display module in the turn-off state, and at the same time, high light emission efficiency in the turn-on state.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display module divided into a light-emitting area and a non-light-emitting area, the display module comprising:
a display panel including a base substrate, a pixel defining layer disposed on the base substrate with an opening defined therethrough to correspond to the light-emitting area, and a display element layer including light-emitting elements distinguished from each other by the pixel defining layer;
an encapsulation substrate disposed on the display panel;
a light control layer disposed on the encapsulation substrate and including a colorant; and
a filling layer including at least one light-converted material having a first structure with a first absorptance with respect to visible light and a second structure with a second absorptance greater than the first absorptance with respect to the visible light, wherein the filling layer is disposed between the display panel and the encapsulation substrate,
wherein each of the light-emitting elements includes:
a first electrode exposed by the opening;
a hole transport area disposed on the first electrode;
a light-emitting layer disposed on the hole transport area;
an electron transport area disposed on the light-emitting layer;
a second electrode disposed on the electron transport area; and
a capping layer disposed on the second electrode,
wherein a structure of the at least one light-converted material changes from the first structure to the second structure when the at least one light-converted material absorbs ultraviolet light.

2. The display module of claim 1, wherein a change of the structure of the at least one light-converted material between the first structure and the second structure is reversible.

3. The display module of claim 1, wherein the at least one light-converted material has the first structure in a turn-on state of the display element layer and has the second structure in a turn-off state of the display element layer.

4. The display module of claim 1, wherein when the at least one light-converted material is in the second structure, the at least one light-converted material selectively absorbs one of a first visible light, a second visible light having a wavelength range different from a wavelength range of the first visible light, and a third visible light having a wavelength range different from the wavelength range of the first visible light and the wavelength range of the second visible light.

5. The display module of claim 4, wherein the at least one light-converted material includes a first light-converted material and a second light-converted material,
Wherein the first light-converted material and the second light-converted material absorb light in different wavelength ranges, respectively.

6. The display module of claim 4, wherein the first visible light has a wavelength range equal to or higher than 410 nm and equal to or less than 500 nm,
wherein the second visible light has a wavelength range equal to or higher than 550 nm and equal to or less than 750 nm,
wherein the third visible light has a wavelength range equal to or higher than 500 nm and equal to or less than 600 nm.

7. The display module of claim 1, wherein the filling layer includes the at least one light-converted material in an amount equal to or greater than 0.1 wt % and equal to or less than 10.0 wt % based on a total weight of the filling layer.

8. The display module of claim 1, wherein the at least one light-converted material includes at least one selected from a spiropyran-based compound and a diarylethene-based compound.

9. The display module of claim 1, further comprising:
an inorganic deposition layer disposed between the capping layer and the filling layer.

10. The display module of claim 1, wherein the display module does not include a polarizer.

11. The display module of claim 1, further comprising:
a light blocking layer overlapping the non-light-emitting area and disposed between the filling layer and the encapsulation substrate.

12. A display module including a first light-emitting area which emits a first light, a second light-emitting area which emits a second light, and a third light-emitting area which emits a third light, the display module comprising:
a display panel including a base substrate, a pixel defining layer disposed on the base substrate with a plurality of openings defined therethrough to correspond to the first to third light-emitting areas, respectively, and a display element layer including first to third light-emitting elements including light-emitting layers disposed in the openings, respectively;
an encapsulation substrate disposed on the display panel;
a sealing portion disposed between the display panel and the encapsulation substrate along an edge of the display panel;
a filling layer including at least one light-converted material having a first structure which transmits all of the first to third lights when the display element layer is in a turn-on state, and a second structure which selectively absorbs one of a first visible light in a wavelength range equal to or greater than 410 nm and equal to or less than 500 nm, a second visible light in a wavelength range equal to or greater than 550 nm and equal to or less than 750 nm, and a third visible light in a wavelength range equal to or greater than 500 nm and equal to or less than 600 nm, wherein the filling layer is disposed in a space defined by the encapsulation substrate, the display panel, and the sealing portion; and
a light control layer disposed on the encapsulation substrate and including a colorant,
wherein each of the first to third light-emitting elements includes:
a first electrode exposed by each opening;
a hole transport area disposed on the first electrode;
a light-emitting layer disposed on the hole transport area;
an electron transport area disposed on the light-emitting layer;
a second electrode disposed on the electron transport area;
a capping layer disposed on the second electrode; and
an inorganic deposition layer disposed on the capping layer.

13. The display module of claim 12, wherein a wavelength range of the first light is equal to or higher than 625 nm and equal to or lower than 675 nm,
wherein a wavelength range of the second light is equal to or higher than 500 nm and equal to or lower than 570 nm,
wherein a wavelength range of the third light is equal to or higher than 410 nm and equal to or lower than 480 nm.

14. The display module of claim 12, wherein the colorant absorbs light in a wavelength range equal to or higher than 490 nm and equal to or lower than 505 nm and light in a wavelength range equal to or higher than 585 nm and equal to or lower than 600 nm.

15. The display module of claim 12, wherein the at least one light-converted material includes:
a first light-converted material which selectively absorbs the first visible light when the at least one light-converted material is in the second structure; and
a second light-converted material which selectively absorbs the second visible light when the at least one light-converted material is in the second structure.

16. The display module of claim 12, wherein the filling layer includes the at least one light-converted material in an amount equal to or greater than 0.1 wt % and equal to or less than 10.0 wt % based on a total weight of the filling layer.

17. The display module of claim 14, wherein the at least one light-converted material includes at least one selected from a spiropyran-based compound and a diarylethene-based compound.

18. The display module of claim 12, wherein the at least one light-converted material in the first structure absorbs ultraviolet light in the first structure, and a structure of the at least one light-converted material changes to the second structure.

19. The display module of claim 18, wherein the at least one light-converted material in the second structure absorbs at least one selected from the first to third lights, and the structure of the at least one light-converted material changes to the first structure.

20. The display module of claim 12, wherein the filling layer further contains a base resin in which the at least one light-converted material is dispersed,
wherein the base resin includes at least one selected from an acrylate-based resin, an epoxy-based resin, and a vinyl-based resin.
